(19) United States
(12) Patent Application Publication
(10) Pub. No.: US 2024/0313085 A1
(43) Pub. Date: Sep. 19, 2024

(54) HIGH ELECTRON MOBILITY TRANSISTOR AND METHOD FOR MANUFACTURING THE SAME

(71) Applicant: Infinity Communication Tech. Inc., Hsinchu City (TW)

(72) Inventor: Shang-Hua TSAI, Hsinchu City (TW)

(21) Appl. No.: 18/463,253

(22) Filed: Sep. 7, 2023

(30) Foreign Application Priority Data
Mar. 13, 2023 (TW) 112109105

(51) Int. Cl. H01L 29/66; H01L 29/20; H01L 29/778

(52) U.S. Cl. CPC H01L 29/66462; H01L 29/2003; H01L 29/7786

(57) ABSTRACT

A high electron mobility transistor includes a body, a transistor unit, and an electrically conducting structure. The body has a first surface and a second surface opposite to the first surface. The transistor unit includes a composite semiconductor layer disposed on the first surface and an electrode component disposed on the composite semiconductor layer opposite to the first surface. The electrode component includes a gate electrode, a source electrode, and a drain electrode which are spaced apart from one another. The source electrode and the drain electrode are disposed at two opposite sides of the gate electrode. The electrically conducting structure includes a back electrode disposed on the second surface and at least one connecting electrode connecting the gate electrode and the back electrode. A method for manufacturing the high electron mobility transistor is also provided herein.

### CROSS-REFERENCE TO RELATED APPLICATION

This application claims priority of Taiwanese Invention Patent Application No. 112109105, filed on Mar. 13, 2023, which is incorporated herein by reference in its entirety.

### FIELD

The disclosure relates to a power transistor and a method for manufacturing the same, and more particularly to a high electron mobility transistor and a method for manufacturing the same.

### BACKGROUND

Power transistors have been widely applied in fast chargers due to advantages such as low driving voltage and fast switching speed. According to current path, power transistors can be divided into horizontal power transistors and vertical power transistors. In particular, a high electron mobility transistor (HEMT) is one of the more commonly used horizontal power transistors. The HEMT includes a heterostructure (or referred to as a composite semiconductor layer) that is formed by connecting two semiconductor materials having different bandgaps (e.g., gallium nitride (GaN) and aluminum gallium nitride (AlGaN)). In such a heterostructure, a two dimensional electron gas (2DEG) with a high planar charge density and a high electron mobility is formed at an interface between the two semiconductor materials, and serves as a carrier channel. In addition, the HEMT is a normally-on device, such as depletion mode GaN HEMT (D-mode GaN HEMT). The D-mode GaN HEMT can be electrically connected to an enhancement mode silicon metal-oxide-semiconductor field-effect transistor (E-mode Si MOSFET) in parallel to form a Cascode structure, which can serve as a normally-off device.

A gate of the common HEMT with the Cascode structure is required to be grounded. Therefore, when designing a circuit pattern of the HEMT, a gate bond pad which is used for wire bonding is usually formed at the gate, such that the gate can be grounded by connecting to an external structure through the gate bond pad. However, parasitic inductance/capacitance may be formed at a wire bonding location of the gate bond pad during formation of a wire for wire bonding on the gate bond pad, resulting in a limitation on the switching speed of the HEMT.

On the other hand, the heterostructure (i.e., the composite semiconductor layer) of the current HEMT is usually formed by epitaxially growing a semiconductor material (e.g., GaN) on a silicon substrate or a sapphire substrate. Epitaxially growing the semiconductor material (e.g., GaN) on the sapphire substrate is widely used for forming the heterostructure of the current HEMT because manufacturing cost for epitaxially growing GaN on the sapphire substrate is lower than that for epitaxially growing GaN on the silicon substrate. Nevertheless, since a thermal conductivity (0.47 W/(cm*K)) of the sapphire substrate is lower than that of the silicon substrate (1.5 W/(cm*K)), the HEMT with the sapphire substrate may have overheating issues during operation.

### SUMMARY

Therefore, an object of the disclosure is to provide a high electron mobility transistor and a method for manufacturing the same that can alleviate at least one of the drawbacks of the prior art.

According to a first aspect of the disclosure, a high electron mobility transistor includes a body, a transistor unit, and an electrically conducting structure.

The body has a first surface and a second surface opposite to the first surface.

The transistor unit includes a composite semiconductor layer disposed on the first surface and an electrode component disposed on the composite semiconductor layer opposite to the first surface. The electrode component includes a gate electrode, a source electrode, and a drain electrode which are spaced apart from one another. The source electrode and the drain electrode are disposed at two opposite sides of the gate electrode.

The electrically conducting structure includes a back electrode disposed on the second surface and at least one connecting electrode connecting the gate electrode and the back electrode.

According to a second aspect of the disclosure, a method for manufacturing a high electron mobility transistor includes the steps of:
a) providing a transistor wafer that includes a substrate and a plurality of transistor units that are disposed on the substrate and that are spaced apart from one another, the substrate being defined to have a plurality of dicing lanes, any two adjacent ones of the transistor units being spaced apart from each other by a respective one of the dicing lanes, each of the transistor units including a gate electrode;
b) forming at least one first electrically conducting portion on each of the transistor units, the at least one first electrically conducting portion being connected to the gate electrode and extending into an adjacent one of the dicing lanes;
c) forming an electrically conducting layer on the substrate opposite to the transistor units;
d) providing a connecting element on the electrically conducting layer opposite to the substrate, followed by removing portions of the substrate and the electrically conducting layer which correspond in position with the dicing lanes, so as to form the substrate into a plurality of bodies on which the transistor units are respectively disposed, and to form the electrically conducting layer into a plurality of back electrodes that are respectively disposed on the bodies and that are disposed on the connecting element to be spaced apart from each other;
e) forming at least one second electrically conducting portion on each of the bodies, the at least one second electrically conducting portion being electrically connected to the back electrode and the at least one first electrically conducting portion of a corresponding one of the transistor units; and
f) removing the connecting element so as to obtain a plurality of the high electron mobility transistors.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic top view illustrating an embodiment of a high electron mobility transistor according to the disclosure.

FIG. 2 is a cross-sectional view taken along line II-Il of FIG. 1.

FIG. 3 is a flow chart illustrating consecutive steps of a method for manufacturing the embodiment of the high electron mobility transistor according to the disclosure.

FIGS. 4 to 12 are schematic views illustrating some intermediate stages of the method as depicted in FIG. 3.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “upper,” “lower,” “on,” “above,” “below,” and the like may be used throughout the disclosure while making reference to the features as illustrated in the drawings. The features may be oriented differently (e.g., rotated 90 degrees or at other orientations) and the spatially relative terms used herein may be interpreted accordingly.

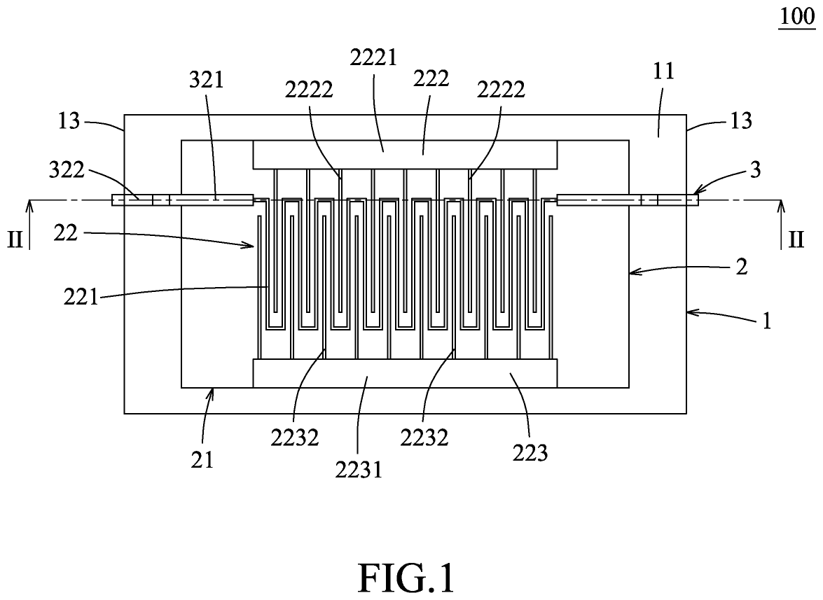

Referring to FIG. 1, a side located below a high electron mobility transistor 100 is defined as the “front side,” a side located above the high electron mobility transistor 100 is defined as the “rear side,” a side located on the left of the high electron mobility transistor 100 is defined as the “left side,” and a side located on the right of the high electron mobility transistor 100 is defined as the “right side.”

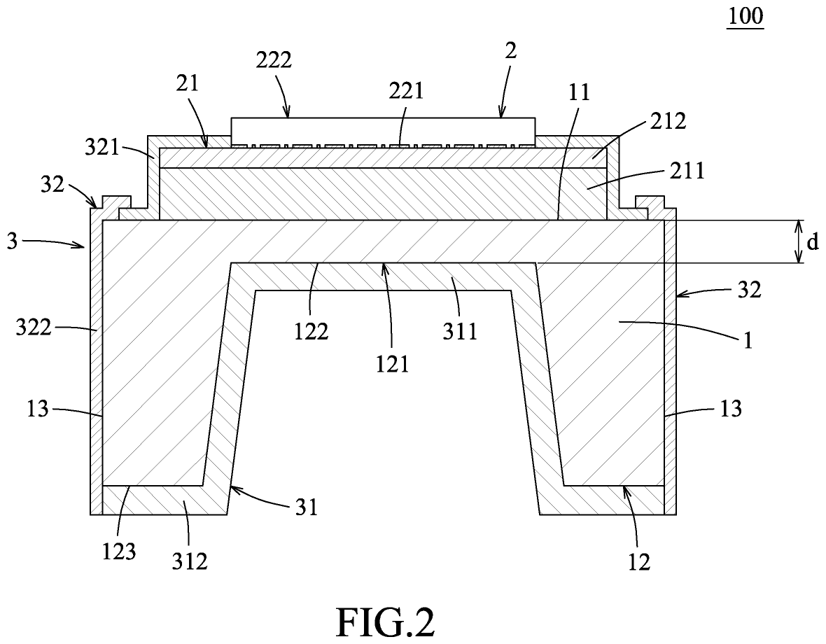

Referring to FIGS. 1 and 2, an embodiment of the high electron mobility transistor 100 according to the present disclosure includes a body 1, a transistor unit 2, and an electrically conducting structure 3. There is no particular limitation on the geometrical shape of the body 1. In some embodiments, the body 1 has the geometrical shape of a rectangular cuboid, and is used for epitaxially growing a semiconductor material (e.g., gallium nitride (GaN)) thereon. There is no particular limitation on the material for forming the body 1. In some embodiments, the body 1 may be made of aluminum oxide (Al₂O₃, also known as sapphire), silicon (Si) or silicon carbide (SiC). In this embodiment, the body 1 is made of Al₂O₃. In addition, the body 1 has a first surface 11, a second surface 12 opposite to the first surface 11, and two opposite side surfaces 13, wherein each of the side surfaces 13 connects the first surface 11 and the second surface 12. As shown in FIG. 2, the body 1 is formed with a recess 121 which corresponds in position with the transistor unit 2. Specifically, the second surface 12 of the body 1 has an inner recess portion 122 that defines the recess 121, and an outer surface portion 123 connected to a periphery of the inner recess portion 122. The inner recess portion 122 has a cross-section having a U shape, and the outer surface portion 123 is flat. The inner recess portion 122 of the second surface 12 is separated from the first surface 11 by a minimum distance (d) (i.e., a thickness of a portion of the body 1 which corresponds in position with the recess 121) ranging from 1 μm to 30 μm. As such, since the thickness of the portion of the body 1 which corresponds in position with the recess 121 is smaller than the remaining portions of the body 1 (e.g., two side portions respectively disposed adjacent to the two opposite side surfaces 13), heat energy generated from the transistor unit 2 during operation and transferred from the body 1 to the second surface 12 may be efficiently dissipated, so as to achieve a better heat dissipating effect. In other embodiments, the second surface 12 of the body 1 may be relatively flat as a whole, which is still capable of transferring the heat energy generated from the transistor unit 2 outward during operation.

The transistor unit 2 includes a composite semiconductor layer 21 disposed on the first surface 11 and an electrode component 22 disposed on the composite semiconductor layer 21 opposite to the first surface 11. The composite semiconductor layer 21 includes a buffer layer 211 disposed on the first surface 11 and a barrier layer 212 disposed on the buffer layer 211 opposite to the first surface 11. The buffer layer 211 is used to form a carrier channel. The barrier layer 212 is provided for the electrode component 22 to be disposed thereon, and is used to isolate the electrode component 22 and the buffer layer 211. Electrons of the buffer layer 211 can be driven by the electrode component 22 to form an electric current or an electron flow. There are no particular limitations on the material for making each of the buffer layer 211 and the barrier layer 212, as long as electron transfer efficiency of the composite semiconductor layer 21 can be efficiently enhanced. In this embodiment, the buffer layer 211 is made of GaN, and the barrier layer 212 is made of aluminum gallium nitride (AlGaN), indium aluminum gallium nitride (InAlGaN) or aluminum nitride (AlN). In other embodiments, the buffer layer 211 and the barrier layer 212 may be made of two semiconductor materials having different energy gaps. For example, the buffer layer 211 may be made of gallium arsenide (GaAs), and the barrier layer 212 may be made of aluminum gallium arsenide (AlGaAs).

The electrode component 22 includes a gate electrode 221, a source electrode 222, and a drain electrode 223 which are spaced apart from one another. There is no particular limitation on the structural shape of the electrode component 22. In this embodiment, the gate electrode 221 is located on a middle portion of the composite semiconductor layer 21 and extends in a serpentine manner in a horizontal direction, and the source electrode 222 and the drain electrode 223 independently has an interdigitated shape and are disposed at two opposite sides (front and rear sides) of the gate electrode 221. The source electrode 222 has a source electrode body 2221 and a plurality of parallel, spaced-apart electrode fingers 2222 each connected to the source electrode body 2221. Likewise, the drain electrode 223 has a drain electrode body 2231 and a plurality of parallel, spaced-apart electrode fingers 2232 each connected to the drain electrode body 2231. The electrode fingers 2222 of the source electrode 222 and the electrode fingers 2232 of the drain electrode 223 are interdigitated with each other, and the gate electrode 221 is disposed thereamong. The gate electrode 221 may be made of an electrically conducting material, for example, but not limited to, metal (e.g., nickel, gold, platinum, aluminum, copper, titanium, titanium nitride, tungsten, tungsten nitride, tantalum, or tantalum nitride), polysilicon, or metal silicide (e.g., an alloy including polysilicon and at least one of tungsten, titanium, cobalt and nickel), and can serve as a switch. Likewise, each of the source electrode 222 and the drain electrode 223 may be made of an electrically conducting material, such as a metal (e.g., nickel, gold, platinum, aluminum, copper, titanium, titanium nitride, tungsten, tungsten nitride, tantalum, or tantalum nitride). When the gate electrode 221 is applied with a negative bias, the carrier channel in the composite semiconductor layer 21 may be depleted, and there exits an open circuit between the source electrode 222 and the drain electrode 223 due to there being no electric current or electron flow therebetween.

The electrically conducting structure 3 includes a back electrode 31 disposed on the second surface 12 and two connecting electrodes 32 that are electrically connected to two opposite sides (left and right sides) of the gate electrode 221, respectively. The back electrode 31 includes a thermally conducting portion 311 disposed on the inner recess portion 122, and a grounding portion 312 connected to the thermally conducting portion 311 and disposed on the outer surface portion 123. A cross-sectional shape of the thermally conducting portion 311 corresponds to that of the inner recess portion 122, and is an inverted U-shape. The thermally conducting portion 311 is used to transfer heat energy from the body 1 to the grounding portion 312. A shape of the grounding portion 312 corresponds to that of the outer surface portion 123 and is a flat shape. The grounding portion 312 is adapted to be bonded to an external structure (not shown) (e.g., a heat sink) for transferring the heat energy from the body 1 and the thermally conducting portion 311 to the external structure, so as to achieve a heat dissipating effect. There is no particular limitation on a bonding method for bonding the grounding portion 312 to the external structure. The grounding portion 312 may be bonded to the external structure through soldering or sticking (e.g., using a thermal paste). In addition, the grounding portion 312 is electrically connected to the external structure.

As shown in FIG. 2, each of the connecting electrodes 32 has a long and thin strip shape, and extends from the gate electrode 221 to be connected to the back electrode 31 along a surface of the composite semiconductor layer 21 and a corresponding one of the side surfaces 13, so as to enable the gate electrode 221 to be grounded in a shortest path, to decrease a contact area between each of the connecting electrodes 32 and the gate electrode 221, and to mitigate parasitic inductance/parasitic capacitance of the gate electrode 221. There is no particular limitation on the number of the connecting electrodes 32. In this embodiment, the number of the connecting electrodes 32 is two. In alternative embodiments, the number of the connecting electrodes 32 may be one and it may be disposed on one of the side surfaces 13. In yet alternative embodiments, the number of the connecting electrodes 32 may be not smaller than three.

Specifically, each of the connecting electrodes 32 includes a first electrically conducting portion 321 and a second electrically conducting portion 322. The first electrically conducting portion 321 is disposed on a portion of an upper surface and a side surface of the composite semiconductor layer 21. The first electrically conducting portion 321 includes an upper part, a middle part, and a lower part, wherein the middle part connects the upper part and the lower part. The upper part of the first electrically conducting portion 321 is disposed on the upper surface of the composite semiconductor layer 21 and is electrically connected to the gate electrode 221, and the lower part of the first electrically conducting portion 321 is disposed on the first surface 11 of the body 1 and the middle part of the first electrically conducting portion 321 is disposed on the side surface of the composite semiconductor layer 21. The second electrically conducting portion 322 of each of the connecting electrodes 32 is disposed on and contacts the corresponding one of the side surfaces 13 of the body 1. The second electrically conducting portion 322 has a first end connected to the lower part of the first electrically conducting portion 321, and a second end connected to the grounding portion 312 of the back electrode 31. As such, the first electrically conducting portion 321 might be stably fixed on the composite semiconductor layer 21, and the second electrically conducting portion 322 might be stably fixed on the body 1, so that the gate electrode 221 might be grounded in a shortest path through the connecting electrode(s) 32, the probability of the connecting electrode(s) 32 being detached due to shaking might be reduced, and a better yield of the high electron mobility transistor 100 might be achieved. In addition, when the gate electrode 221 is electrically connected to the grounding portion 312 of the back electrode 31 through the connecting electrode 32, an electric current might flow from the gate electrode 221 to the external structure (electrically connected to the grounding portion 312) through the grounding portion 312, thereby increasing a switching speed of the high electron mobility transistor 100.

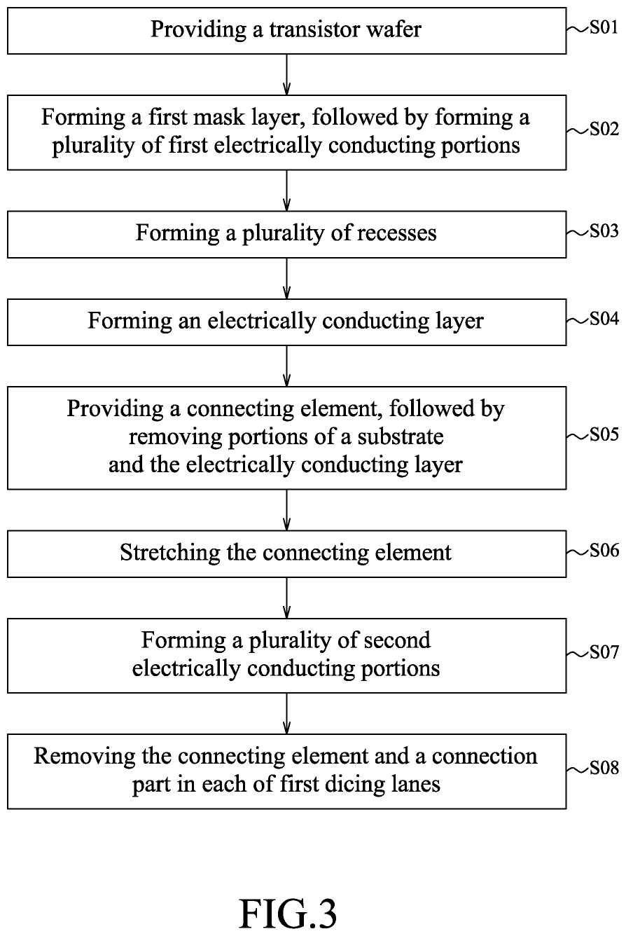

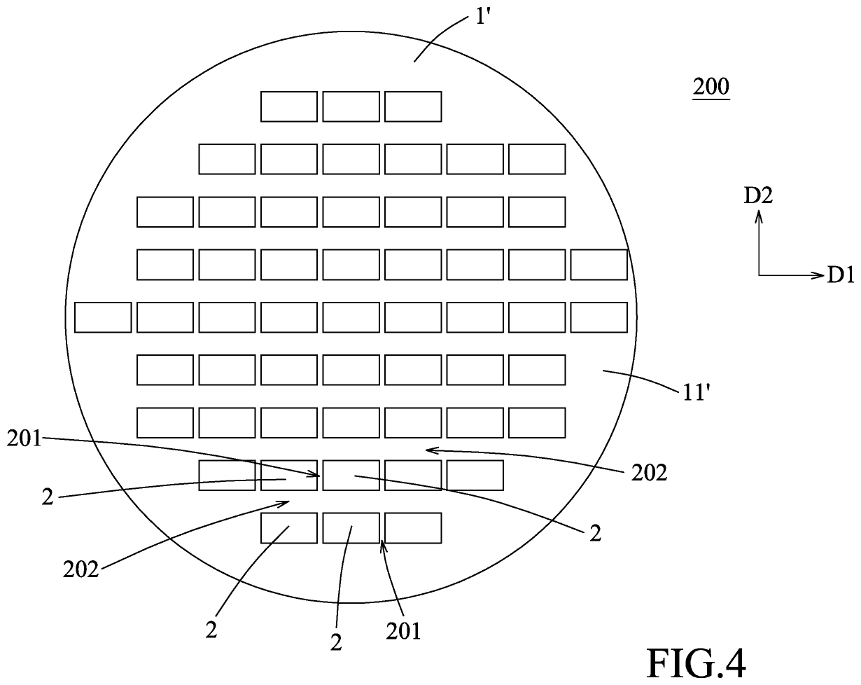

Referring to FIG. 3, this disclosure also provides a method for manufacturing the embodiment of the high electron mobility transistor 100, which includes the following consecutive steps S01 to S08. FIGS. 4 to 12 illustrate intermediate stages of the method for manufacturing the embodiment of the high electron mobility transistor 100.

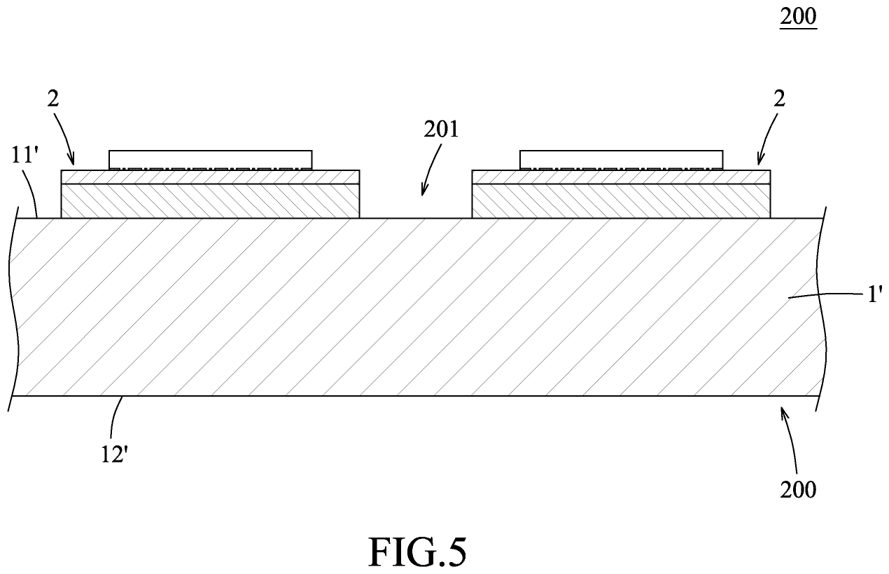

In step S01, as shown in FIGS. 4 and 5, a transistor wafer 200 is provided. The transistor wafer 200 includes a substrate 1′ and a plurality of the transistor units 2 that are disposed on a first surface 11′ of the substrate 1′ in an array and that are spaced apart from one another. The substrate 1′ and the body 1 are made of the same material. The substrate 1′ is defined to have a plurality of first dicing lanes 201 and a plurality of second dicing lanes 202. Any two adjacent ones of the transistor units 2 are spaced apart from each other by a respective one of the first dicing lanes 201 in a first direction (D1). Any two adjacent ones of the transistor units 2 are spaced apart from each other by a respective one of the second dicing lanes 202 in a second direction (D2) transverse to the first direction (D1).

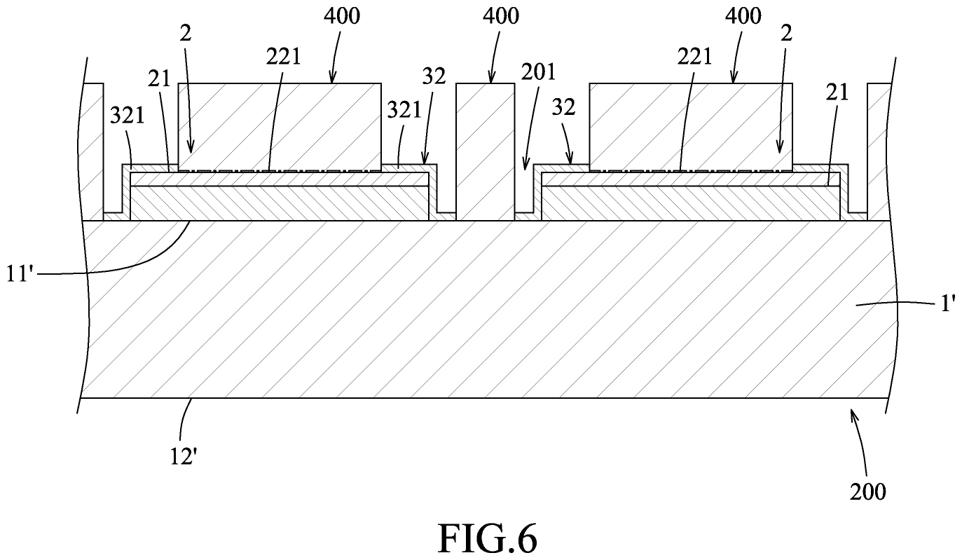

In step S02, as shown in FIGS. 5 and 6, a first mask layer 400 is formed, followed by forming the first electrically conducting portions 321 on each of the transistor units 2. Step S02 may include sub-steps (i) and (ii). In sub-step (i), a photoresist layer (not shown) is spin-coated on a structure shown in FIG. 5, followed by being exposed and developed, so as to form the first mask layer 400. The first mask layer 400 covers the substrate 1′ and the transistor units 2, but exposes a portion of the composite semiconductor layer 21 of each of the transistor units 2 that is adjacent to two ends of the gate electrode 221 and portions of the first dicing lanes 201 that are adjacent to the transistor units 2. The first mask layer 400 has a pattern that corresponds to a pattern (a strip shape extending in the first direction (D1)) of the first electrically conducting portions 321. In sub-step (ii), a metal layer (e.g., nickel, gold, platinum, aluminum, copper, titanium, titanium nitride, tungsten, tungsten nitride, tantalum, tantalum nitride, or other suitable metals) is formed on the exposed portions of the transistor units 2 and the exposed portions of the first dicing lanes 201 by sputtering, evaporation or chemical deposition, so as to form the first electrically conducting portions 321. The first mask layer 400 is then removed. Each of the first electrically conducting portions 321 is connected to the gate electrode 221 of a corresponding one of the transistor units 2, and extends into an adjacent one of the first dicing lanes 201. It should be noted that two adjacent ones of the first electrically conducting portions 321 that extend into the same first dicing lanes 201 are separated from each other due to the presence of the first mask layer 400 in a portion of each of the first dicing lanes 201.

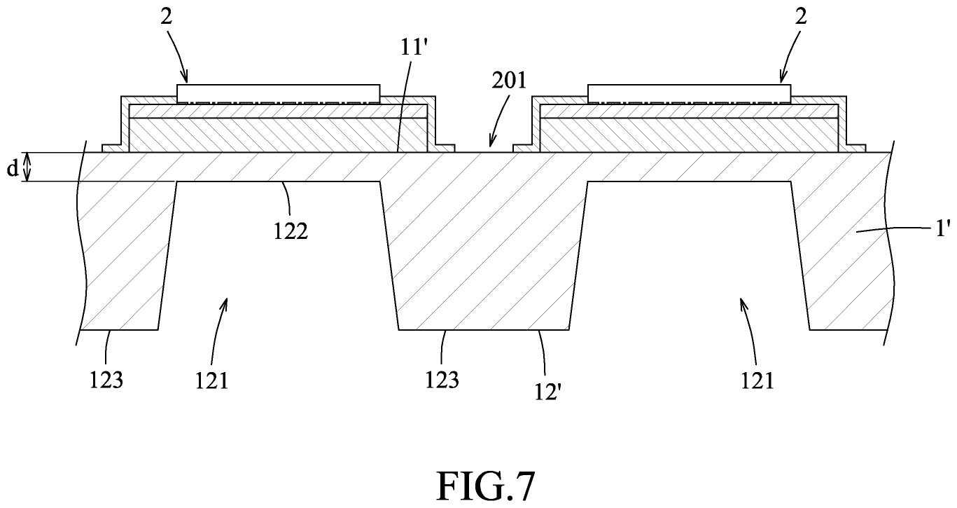

In step S03, as shown in FIG. 7, the substrate 1′ is formed with a plurality of recesses 121 that are indented from a second surface 12′ (opposite to the first surface 11′) of the substrate 1′ toward the first surface 11′ and that correspond in position with the transistor units 2, respectively. Step S03 may be performed by a physical drilling process (e.g., laser drilling or sandblasting). After this step, the second surface 12′ is formed with a plurality of the inner recess portions 122 and a plurality of the outer surface portions 123. The minimum distance (d) between each of the inner recess portions 122 and the first surface 11′ may vary depending on practical needs.

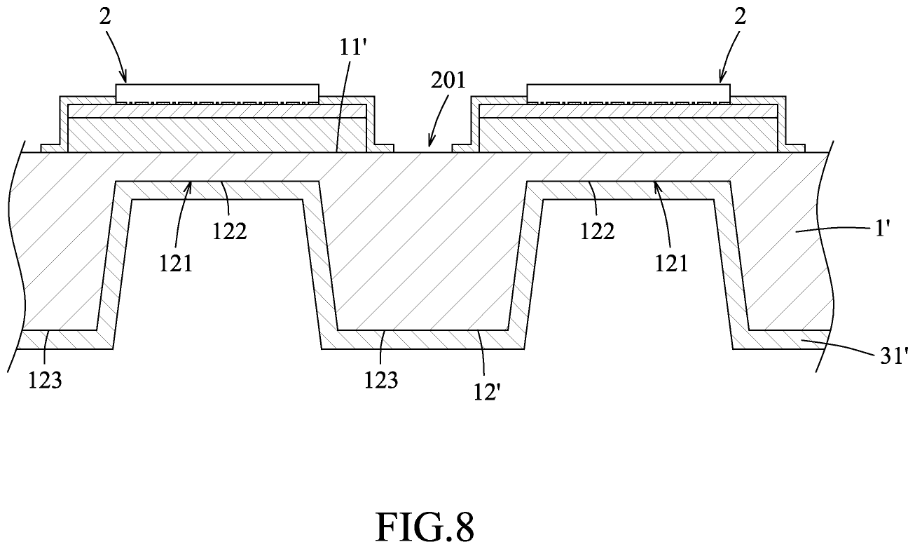

In step S04, as shown in FIG. 8, an electrically conducting layer 31′ is formed on the second surface 12′ (i.e., on the inner recess portions 122 and the outer surface portions 123) of the substrate 1′. Step S04 may be performed by sputtering, evaporation, electroplating, or chemical deposition. The electrically conducting layer 31′ is to be formed into the back electrode 31 and is made of the same material as that of the back electrode 31 that has a high thermal conductivity and high electrical conductivity, such as gold, silver, copper, or aluminum.

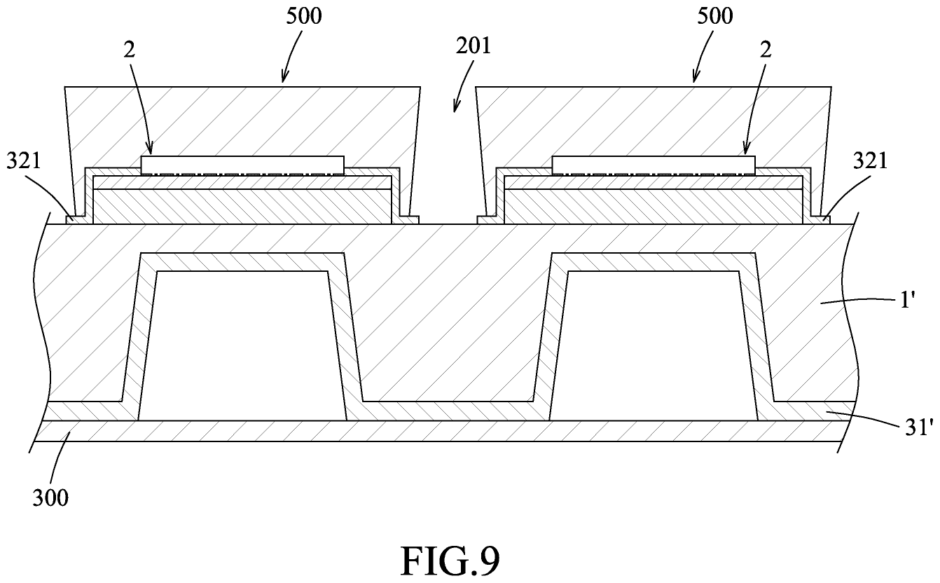

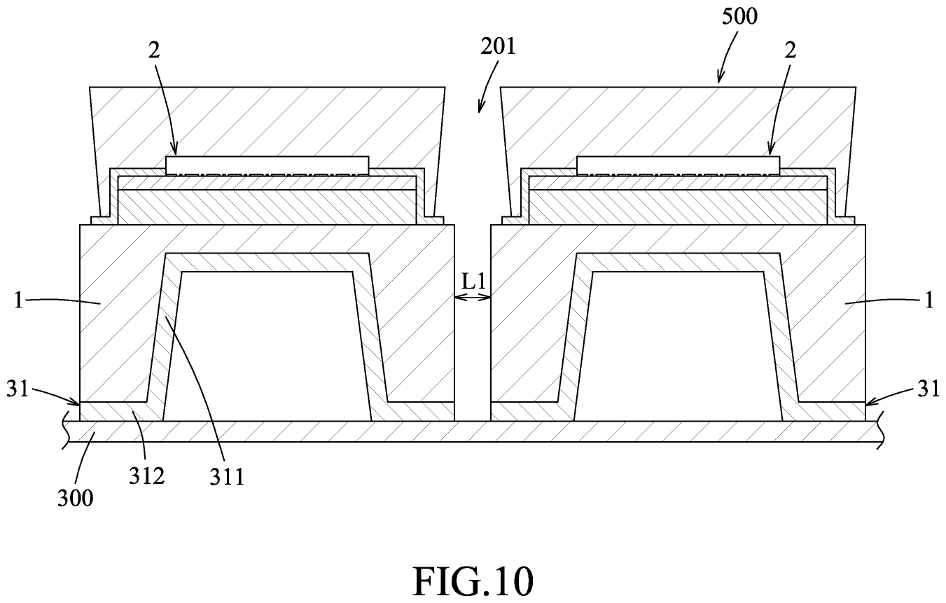

In step S05, as shown in FIGS. 9 and 10, a connecting element 300 is provided on the electrically conducting layer 31′ opposite to the substrate 1′, followed by removing portions of the substrate 1′ and the electrically conducting layer 31′ which correspond in position with the first dicing lanes 201. The connecting element 300 may be made of a stretchable material (e.g., solvent resistance dicing tape). In this step, before removal of the portions of the substrate 1′ and the electrically conducting layer 31′, a second mask layer 500 may be formed to respectively cover the transistor units 2 and portions of the first electrically conducting portions 321, and to expose the first dicing lanes 201 and the lower part of each of the first electrically conducting portions 321. The process for forming the second mask layer 500 may be the same as that for forming the first mask layer 400, and thus further details thereof is omitted for the sake of brevity. In this step, after formation of the second mask layer 500, removal of the portions of the substrate 1′ and the electrically conducting layer 31′ is conducted using a dicing technique (e.g., dicing saw or laser cut) starting from the first dicing lanes 201 toward the connecting element 300, so as to remove the portions of the substrate 1′ and the electrically conducting layer 31′ which correspond in position with the first dicing lanes 201 and to retain the connecting element 300. After this step, the substrate 1′ is formed into a plurality of the bodies 1 on which the transistor units 2 are respectively disposed, and the electrically conducting layer 31′ is formed into a plurality of the back electrodes 31 that are respectively disposed on the bodies 1 and that are disposed on the connecting element 300 to be spaced apart from each other. The arrangement of the transistor units 2 remains unchanged as an array.

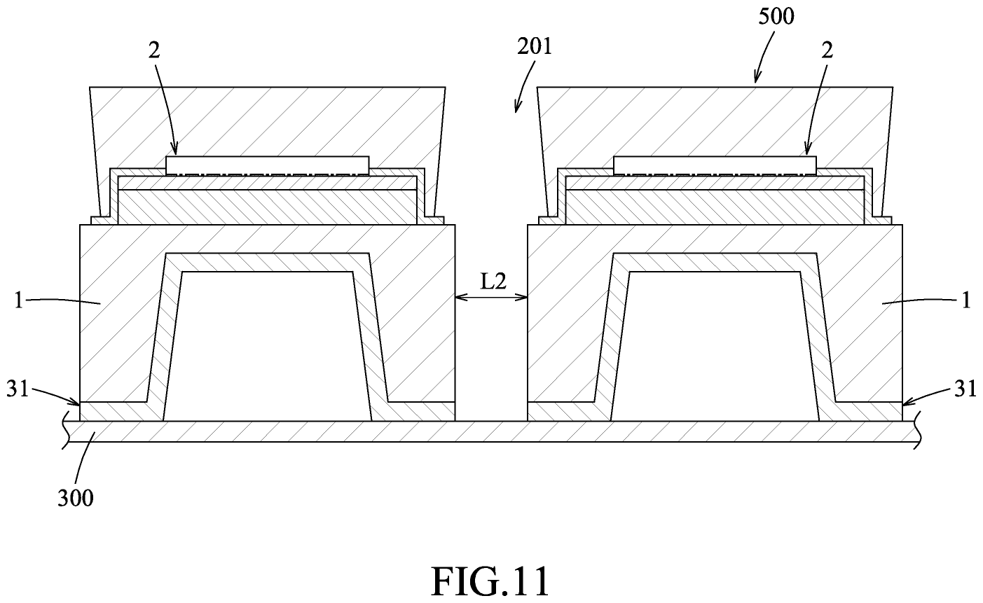

In step S06, as shown in FIGS. 10 and 11, the connecting element 300 is stretched so as to increase a spacing between two adjacent ones of the bodies 1. Before this step, two adjacent ones of the bodies 1 are separated from each other by a first spacing (L1) (see FIG. 10). After this step, the two adjacent ones of the bodies 1 are separated from each other by a second spacing (L2) (see FIG. 11). The second spacing (L2) is larger than the first spacing (L1).

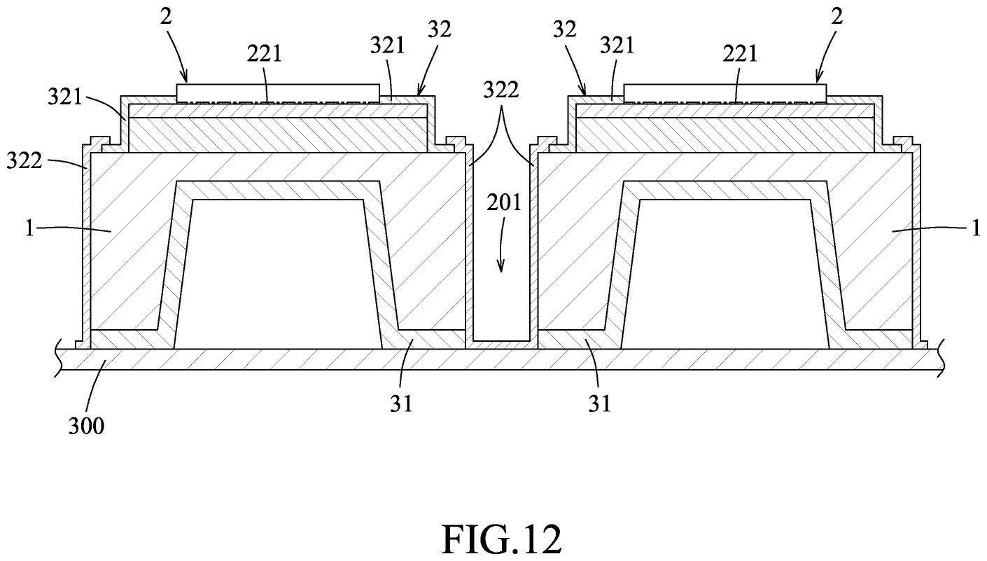

In step S07, as shown in FIG. 12, a plurality of second electrically conducting portions 322 are respectively formed on the bodies 1 with the second mask layer 500 as a mask. Each of the second electrically conducting portions 322 is electrically connected to a corresponding one of the back electrodes 31 and a corresponding one of the first electrically conducting portions 321. Step S07 may be performed by depositing a metallic layer for forming the second electrically conducting portions 322 on the structure shown in FIG. 11 through sputtering, evaporation, electroplating, or chemical deposition, followed by removing the second mask layer 500, so as to form the second electrically conducting portions 322. The metallic layer formed in each of the first dicing lanes 201 is formed as a connection part that interconnects two adjacent ones of the second electrically conducting portions 322. There is no particular limitation on the material for forming the second electrically conducting portions 322. The second electrically conducting portions 322 may be made of a metal (e.g., nickel, gold, platinum, aluminum, copper, titanium, titanium nitride, tungsten, tungsten nitride, tantalum, or tantalum nitride). In this embodiment, each of the second electrically conducting portions 322 is electrically connected to the corresponding one of the back electrodes 31 and the corresponding one of the first electrically conducting portions 321 through metallic bonding, so as to achieve a better electrical conductivity.

In step S08, the connecting element 300 and the connection part in each of the first dicing lanes 201 are removed (not shown), so as to obtain a plurality of the high electron mobility transistors 100. It is noted that step S06 need not be performed, i.e., the two adjacent ones of the bodies 1 may be separated from each other by the first spacing (L1).

In some embodiments, step S03 may be omitted, and in step S04, the second surface 12′ of the substrate 1′ on which the electrically conducting layer 31′ is formed is flat, which is conducive to increasing a contact area between the back electrode 31 and the external structure. In addition, in such case, after step S07, each of the second electrically conducting portions 322 is still electrically connected to the back electrode 31 to serve as a ground terminal of a corresponding one of the gate electrodes 221.

In sum, in a packaging process of the high electron mobility transistor 100, by having the connecting electrode 32 which electrically connects the gate electrode 221 and the back electrode 31, the gate electrode 221 might be grounded directly through the back electrode 31 being electrically connected to the external structure, so as to shorten a path of the gate electrode 221 to ground, and to further mitigate the parasitic inductance or parasitic capacitance of the gate electrode 221, and increase the switching speed of the high electron mobility transistor 100. In addition, the connecting electrode 32 is bonded to the gate electrode 221 through a coating method (e.g., deposition), which is conducive to enhancing a bond strength between the connecting electrode 32 and the gate electrode 221, reducing a contact area therebetween, and shrinking the size of the high electron mobility transistor 100. In addition, with the provision that the back electrode 31 (in particular, the thermally conducting portion 311) is used to transfer a heat energy of the transistor unit 2 to the external structure, a temperature of the transistor unit 2 generated during operation might be lowered, so as to provide a better heat dissipating effect for the high electron mobility transistor 100.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A high electron mobility transistor, comprising:
a body having a first surface and a second surface opposite to said first surface;
a transistor unit including a composite semiconductor layer disposed on said first surface and an electrode component disposed on said composite semiconductor layer opposite to said first surface, said electrode component including a gate electrode, a source electrode, and a drain electrode which are spaced apart from one another, said source electrode and said drain electrode disposed at two opposite sides of said gate electrode; and
an electrically conducting structure including a back electrode disposed on said second surface and at least one connecting electrode connecting said gate electrode and said back electrode.

2. The high electron mobility transistor as claimed in claim 1, wherein said body further includes two opposite side surfaces each of which connects said first surface and said second surface, said at least one connecting electrode being disposed on one of said side surfaces and said composite semiconductor layer.

3. The high electron mobility transistor as claimed in claim 1, wherein said composite semiconductor layer includes a buffer layer disposed on said first surface and a barrier layer disposed on said buffer layer opposite to said first surface, said electrode component being disposed on said barrier layer.

4. The high electron mobility transistor as claimed in claim 3, wherein said body is made of aluminum oxide.

5. The high electron mobility transistor as claimed in claim 3, wherein said buffer layer is made of gallium nitride.

6. The high electron mobility transistor as claimed in claim 3, wherein said barrier layer is made of aluminum gallium nitride.

7. The high electron mobility transistor as claimed in claim 1, wherein said body is formed with a recess which corresponds in position with said transistor unit, said second surface having an inner recess portion that defines said recess and an outer surface portion connected to a periphery of said inner recess portion, said back electrode including a thermally conducting portion disposed on said inner recess portion, and a grounding portion connected to said thermally conducting portion, disposed on said outer surface portion and electrically connected to said at least one connecting electrode.

8. The high electron mobility transistor as claimed in claim 7, wherein said body is made of aluminum oxide.

9. The high electron mobility transistor as claimed in claim 7, wherein said inner recess portion of said second surface is separated from said first surface by a minimum distance ranging from 1 μm to 30 μm.

10. A method for manufacturing a high electron mobility transistor, comprising the steps of:
a) providing a transistor wafer that includes a substrate and a plurality of transistor units that are disposed on the substrate and that are spaced apart from one another, the substrate being defined to have a plurality of dicing lanes, any two adjacent ones of the transistor units being spaced apart from each other by a respective one of the dicing lanes, each of the transistor units including a gate electrode;
b) forming at least one first electrically conducting portion on each of the transistor units, the at least one first electrically conducting portion being connected to the gate electrode and extending into an adjacent one of the dicing lanes;
c) forming an electrically conducting layer on the substrate opposite to the transistor units;
d) providing a connecting element on the electrically conducting layer opposite to the substrate, followed by removing portions of the substrate and the electrically conducting layer which correspond in position with the dicing lanes, so as to form the substrate into a plurality of bodies on which the transistor units are respectively disposed, and to form the electrically conducting layer into a plurality of back electrodes that are respectively disposed on the bodies and that are disposed on the connecting element to be spaced apart from each other;
e) forming at least one second electrically conducting portion on each of the bodies, the at least one second electrically conducting portion being electrically connected to the back electrode and the at least one first electrically conducting portion of a corresponding one of the transistor units; and
f) removing the connecting element so as to obtain a plurality of the high electron mobility transistors.

11. The method as claimed in claim 10, further comprising, after step b) and before step c), forming the substrate with a plurality of recesses that are indented from a surface of the substrate opposite to the transistor units toward the transistor units and that correspond in position with the transistor units, respectively, in step c), the electrically conducting layer being formed on the surface of the substrate where the recesses are formed.

12. The method as claimed in claim 10, wherein,
in step d), the connecting element is made of a stretchable material, and
the method further includes, after step d) and before step e), stretching the connecting element so as to increase a spacing between two adjacent ones of the bodies.

13. The method as claimed in claim 10, wherein in step d), before removal of the portions of the substrate and the electrically conducting layer, a mask layer is formed to respectively cover the transistor units and portions of the first electrically conducting portions, and to expose the dicing lanes.

14. The method as claimed in claim 10, wherein in step d), removal of the portions of the substrate and the electrically conducting layer is conducted using a dicing technique, and is started from the dicing lanes toward the connecting element.
